(19) United States
(12) Patent Application Publication
(10) Pub. No.: US 2026/0223500 A1
(43) Pub. Date: Jul. 30, 2026

(54) LIGHT-EMITTING DEVICE

(71) Applicant: Ennostar Corporation, Hsinchu City (TW)

(72) Inventors: Chun-Hung LIU, Hsinchu City (TW); Yi-Fei WANG, Hsinchu City (TW); Ying-Yang SU, Hsinchu City (TW); Jen-Chieh YU, Hsinchu City (TW); Min-Hsun HSIEH, Hsinchu City (TW); Wei-Yu CHEN, Hsinchu City (TW)

(21) Appl. No.: 19/454,059

(22) Filed: Jan. 20, 2026

(30) Foreign Application Priority Data
Jan. 24, 2025 (TW) 114103287

(51) Int. Cl. H10H 20/857; H10H 20/831; H10H 29/14; H10H 29/80; H10H 29/85; H10H 29/852

(52) U.S. Cl. CPC H10H 20/857; H10H 20/8312; H10H 29/14; H10H 29/8323; H10H 29/852; H10H 29/857

(57) ABSTRACT

A light-emitting device includes a substrate, a first surface electrode, a second surface electrode, a first light-emitting element, a second light-emitting element, and a first conductive connector. The first surface electrode and the second surface electrode are disposed on the substrate. The first light-emitting element is disposed on the substrate and electrically connected to the first surface electrode, and has a first topmost surface. The second light-emitting element is disposed on the substrate and electrically connected to the second surface electrode, and has a second topmost surface. The first conductive connector has a metal stack and a third topmost surface, and electrically connects the first surface electrode and the first light-emitting element. The third topmost surface of the first conductive connector is not lower than the second topmost surface of the second light-emitting element.

### CROSS-REFERENCE TO RELATED APPLICATIONS

This application claims priority to, and the benefit of, Taiwan Patent Application Number 114103287 filed on Jan. 24, 2025, the entirety of which is hereby incorporated by reference.

### TECHNICAL FIELD

The present disclosure relates to a light-emitting device, and more particularly, to light-emitting device which has a conductive connector.

### BACKGROUND

The light-emitting diode (LED), due to advantages such as low power consumption and long operating life, has increasingly replaced traditional light sources like incandescent bulbs and fluorescent lamps. LEDs are employed in a wide range of applications, including traffic signals, backlight modules, street lighting, medical equipment, and display pixels.

At present, the overall dimensions of LEDs continue to decrease, while the required number of LEDs integrated within a single device continues to increase. Accordingly, increasing the number of LEDs per unit area within a single device has become a critical technical challenge in the manufacture of light-emitting devices.

### SUMMARY

The present disclosure provides a light-emitting device including a substrate, a first surface electrode, a second surface electrode, a first light-emitting element, a second light-emitting element, and a first conductive connector. The first surface electrode and the second surface electrode are disposed on the substrate. The first light-emitting element is disposed on the substrate and electrically connected to the first surface electrode, and has a first topmost surface. The second light-emitting element is disposed on the substrate and electrically connected to the second surface electrode, and has a second topmost surface. The first conductive connector includes a metal stack and a third topmost surface, and electrically connects the first surface electrode and the first light-emitting element. The third topmost surface of the first conductive connector is not lower than the second topmost surface of the second light-emitting element.

### BRIEF DESCRIPTION OF THE DRAWINGS

The embodiments of the present disclosure can be more fully understood by referring to the following detailed description in conjunction with the accompanying drawings. It should be noted that certain components may not be drawn to scale. For clarity, the dimensions of some components may be exaggerated or reduced.

FIG. 1A is a cross-sectional view of a light-emitting device according to an embodiment of the present disclosure.

FIG. 1B is a top view of the light-emitting device of FIG. 1A.

FIG. 1C is a cross-sectional view of region G1 of FIG. 1A in the X direction.

FIG. 1D is an enlarged view of region G2 of FIG. 1A.

FIG. 2A is a cross-sectional view of a light-emitting device according to an embodiment of the present disclosure.

FIG. 2B is a top view of the light-emitting device of FIG. 2A.

FIG. 3A is a cross-sectional view of a light-emitting device according to an embodiment of the present disclosure.

FIG. 3B is a top view of the light-emitting device of FIG. 3A.

FIG. 3C is a cross-sectional view of region G1 of FIG. 3A in the X direction.

FIG. 4 is a cross-sectional view of a light-emitting device according to an embodiment of the present disclosure.

FIG. 5 is a cross-sectional view of a light-emitting device according to an embodiment of the present disclosure.

FIG. 6 is a cross-sectional view of a light-emitting device according to an embodiment of the present disclosure.

FIGS. 7A to 7D illustrate a manufacturing process of a light-emitting device according to an embodiment of the present disclosure.

FIGS. 8A to 8H illustrate a manufacturing process of a conductive connector according to an embodiment of the present disclosure.

### DETAILED DESCRIPTION

The semiconductor structures of the embodiments disclosed herein, as well as methods of forming the same, are described in detail below. It should be understood that the following description sets forth numerous different embodiments to illustrate various aspects of the present disclosure. The specific components and configurations described are provided solely to clearly and simply explain certain embodiments, and are not intended to limit the scope of the disclosure. In addition, similar and/or corresponding reference numerals may be used across different embodiments to denote similar and/or corresponding elements for clarity. The use of such similar and/or corresponding reference numerals is for convenience in description and does not imply any relationship among the different embodiments and/or structures discussed.

As used in the specification, the terms “about,” “approximately,” and “substantially” generally indicate within 20% of a given value or range, preferably within 10%, and more preferably within 5%, 3%, 2%, 1%, or 0.5%. It should be noted that numerical values provided in the specification are to be understood as approximate values. Accordingly, even where the terms “about,” “approximately,” or “substantially” are not expressly used, their meanings may be implied unless otherwise specified.

As used in the specification, the terms “about,” “approximately,” and “substantially” generally indicate within 20% of a given value or range, preferably within 10%, and more preferably within 5%, 3%, 2%, 1%, or 0.5%. It should be noted that numerical values provided in the specification are to be understood as approximate values. Accordingly, even where the terms “about,” “approximately,” or “substantially” are not expressly used, their meanings may be implied unless otherwise specified.

The terms “first,” “second,” and similar expressions are used to name different components or distinguish among different embodiments or ranges, and are not intended to indicate any upper or lower limits on quantity, nor to specify an order of manufacture or placement.

In this disclosure, directional references are not limited to the orthogonal axes of a Cartesian coordinate system (e.g., X, Y, and Z), and may be interpreted more broadly. For example, the X, Y, and Z axes may denote mutually perpendicular axes, or may represent different directions that are not perpendicular. For clarity and illustrative purposes, some of the cross-sectional schematic views described below depict sections taken in the XY plane, and certain top views are presented as observed along the Y direction.

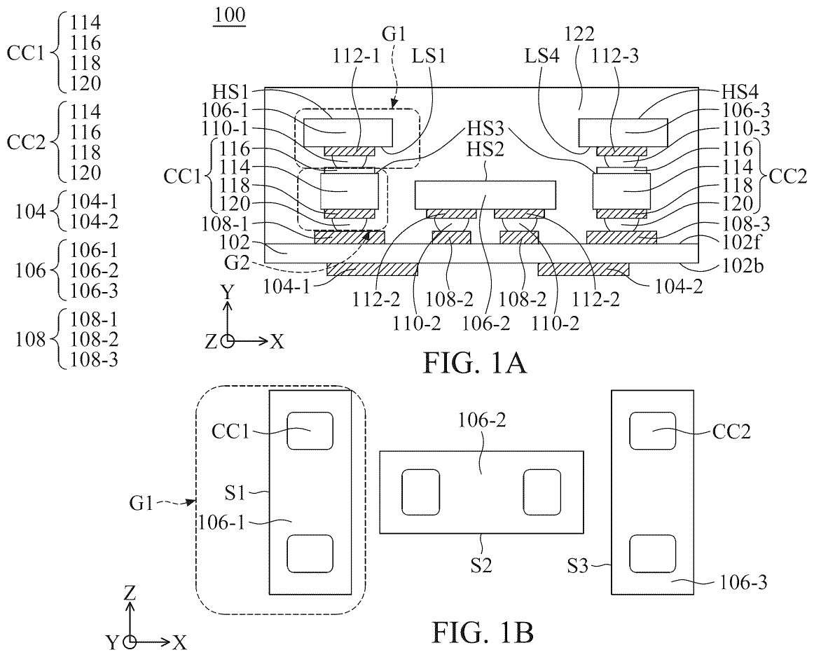

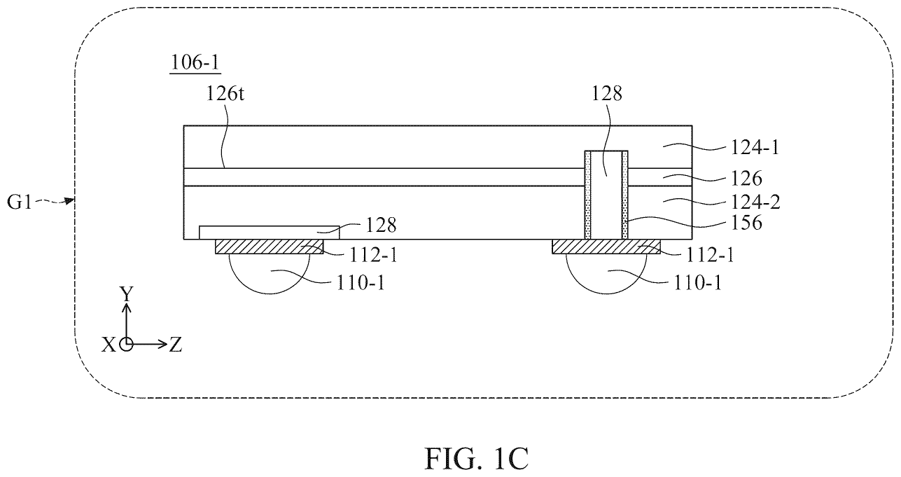

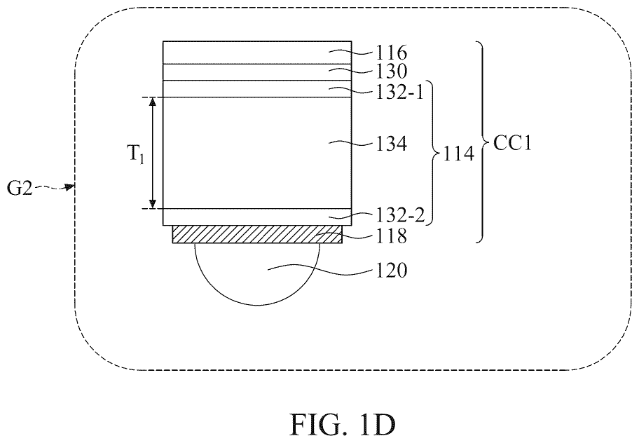

FIG. 1A is a cross-sectional view of a light-emitting device according to one embodiment of the present disclosure. For clarity, some components of the light-emitting device in the following figures have been omitted.

Referring to FIG. 1A, in one embodiment, the light-emitting device 100 includes a substrate 102, a light-emitting element 106, and conductive connectors CC1 and CC2. In some embodiments, the light-emitting element 106 includes three light-emitting elements 106-1, 106-2, and 106-3. In one embodiment, each conductive connector CC1, CC2 includes a metal stack 114, an upper electrode 116, a lower electrode 118, and a bump 120. The foregoing components are described in detail below.

In one embodiment, the substrate 102 is transmissive to light emitted by the light-emitting element 106. The substrate 102 includes epoxy, silicone, sapphire, glass, silicon nitride, or aluminum oxide, but is not limited thereto.

As shown in FIG. 1A, in one embodiment, the substrate 102 includes a rear electrode 104 disposed on a backside 102b of the substrate and a front electrode 108 (also referred to as a surface electrode 108) disposed on a front side 102f of the substrate. The front electrode 108 is used to electrically connect the substrate 102 to components disposed on it (e.g., the light-emitting element 106), and the rear electrode 104 is used to electrically connect the substrate 102 to external components (e.g., a TFT backplane or a printed circuit board).

In some embodiments, the rear electrode 104 and the front electrode 108 include the same or different conductive materials. The conductive material includes chromium (Cr), aluminum (Al), nickel (Ni), gold (Au), platinum (Pt), tin (Sn), copper (Cu), alloys thereof, or stacks thereof.

As shown in FIG. 1A, in one embodiment, the light-emitting element 106 is disposed on the substrate 102 and includes three light-emitting elements 106-1, 106-2, and 106-3. The light-emitting elements 106-1, 106-2, and 106-3 are configured to emit blue, red, and green light, respectively. However, the present disclosure is not limited thereto; in other embodiments, the light-emitting element 106 includes any number of light-emitting elements of any color light.

In one embodiment, the light-emitting element 106-1 has a multi-quantum well (MQW) structure as shown in FIG. 1C, and the light-emitting elements 106-2 and 106-3 have the same or similar structures (not shown).

The light-emitting element 106-1 includes an upper semiconductor layer 124-1, a lower semiconductor layer 124-2, a multi-quantum well structure 126, an ohmic contact layer 128, an insulating sidewall 156, a lower electrode 112-1, and a lower bump 110-1. In one embodiment, the multi-quantum well structure 126 for emitting light is sandwiched by the upper semiconductor layer 124-1 and the lower semiconductor layer 124-2. The upper semiconductor layer 124-1, the lower semiconductor layer 124-2 or both include a reflective structure to reflect light emitted by the multi-quantum well structure 126. In one embodiment, the reflective structure includes a distributed Bragg reflector (DBR).

In one embodiment, the multi-quantum well structure 126 includes III-V element such as Al, Ga, In, As, or P, or III-V compound semiconductor such as InGaAs, AlGaAsP, GaAsP, InGaAsP, AlGaAs, AlGaInAs, InGaP, AlGaInP, InGaN, AlGaN, or AlInGaN. In one embodiment, each of the upper semiconductor layer 124-1 and the lower semiconductor layer 124-2 includes III-V compound semiconductor, such as InGaAs, GaAs, GaP, InP, AlGaInP, AlGaAs, and/or combinations thereof.

As shown in FIG. 1C, the upper semiconductor layer 124-1 and the lower semiconductor layer 124-2 each include an ohmic contact layer 128. The ohmic contact layer 128 electrically connects the upper semiconductor layer 124-1 and the lower semiconductor layer 124-2 to the lower electrode 112-1 and the lower bump 110-1. In one embodiment, the ohmic contact layer 128 includes a semiconductor such as gallium arsenide (GaAs), or a conductive oxide such as indium tin oxide (ITO) or indium zinc oxide (IZO). In one embodiment, the materials of the lower electrode 112-1 and the lower bump 110-1 can be referred to the conductive materials of the rear electrode 104 and the front electrode 108.

As shown in FIG. 1C, the upper semiconductor layer 124-1 and the lower semiconductor layer 124-2 respectively connect to the lower electrode 112-1 by the ohmic contact layer 128. The lower electrode 112-1 contacts and electrically connects to the lower bump 110-1. The ohmic contact layer 128 connected to the upper semiconductor layer 124-1 extends through the lower semiconductor layer 124-2 and the multi-quantum well structure 126, and is electrically isolated from the lower semiconductor layer 124-2 and the multi-quantum well structure 126 by the insulating sidewall 156. In one embodiment, the insulating sidewall 156 includes silicon oxide (SiOₓ) and silicon nitride (SiNₓ).

Referring to FIG. 1A, the light-emitting elements 106-1 and 106-3 are disposed on the substrate 102 via the conductive connectors CC1 and CC2, respectively, while the light-emitting element 106-2 is directly disposed on the substrate 102. The topmost surface of the light-emitting element 106-2 is lower than the topmost surfaces of the light-emitting elements 106-1 and 106-3.

As shown in FIG. 1A, in one embodiment, each conductive connector CC1, CC2 includes an upper electrode 116, a metal stack 114, a lower electrode 118, and a bump 120. As shown in FIG. 1D, the metal stack 114 includes an adhesion layer 130, a first diffusion barrier 132-1, a metal pillar 134, and a second diffusion barrier 132-2.

As shown in FIG. 1A, in the conductive connectors CC1 and CC2, the lower electrode 118 is disposed over the front electrode 108-1 or 108-3. The conductive connector CC1 directly contacts the lower bump 110-1 of the light-emitting element 106-1, and the conductive connector CC2 directly contacts the lower bump 110-3 of the light-emitting element 106-3.

As shown in FIGS. 1A and 1D, in one embodiment, the upper electrode 116 includes a metal oxide or a metal. The metal oxide includes indium tin oxide (ITO), indium oxide (InO), tin oxide (SnO), cadmium tin oxide (CTO), antimony tin oxide (ATO), aluminum-doped zinc oxide (AZO), zinc tin oxide (ZTO), gallium-doped zinc oxide (GZO), indium tungsten oxide (IWO), zinc oxide (ZnO), and indium zinc oxide (IZO). The metal includes germanium (Ge), beryllium (Be), zinc (Zn), gold (Au), platinum (Pt), tin (Sn), titanium (Ti), aluminum (Al), nickel (Ni), copper (Cu), alloys thereof, or stacks thereof. The materials of the lower electrode 118 and the bump 120 can be referred to the materials of the lower electrode 112-1 and the lower bump 110-1 as mentioned above.

As shown in FIG. 1D, in one embodiment, the metal pillar 134 includes chromium (Cr), aluminum (Al), nickel (Ni), copper (Cu), alloys thereof, or stacks thereof.

Referring to FIGS. 1A and 1D, in one embodiment, the metal pillar 134 has thickness T₁. The topmost surface HS3 of the metal stack 114 can be made not lower than the topmost surface HS2 of the light-emitting element 106-2 by adjusting the thickness T₁, thereby ensuring that the bottom surfaces LS1 and LS4 of the light-emitting elements 106-1 and 106-3 are at least as high as the topmost surface HS2 of the light-emitting element 106-2. In another embodiment, the heights of the conductive connectors CC1 and CC2 can be individually adjusted so that the topmost surface HS1 of the light-emitting element 106-1 and the topmost surface HS4 of the light-emitting element 106-3 are substantially located at the same elevation.

As shown in FIG. 1D, the diffusion barrier 132-1 is disposed on the side of metal pillar 134 near the upper electrode 116, and the diffusion barrier 132-2 is disposed on the side of the metal pillar 134 near the lower electrode 118. The diffusion barriers 132-1 and 132-2 are respectively used to block metal of the metal pillar 134 from diffusing into the upper electrode 116 and the lower electrode 118. Accordingly, the materials of the diffusion barriers 132-1 and 132-2 are selected to be compatible with the material of the metal pillar 134 and effective at blocking diffusion thereof. In one embodiment, the metal pillar 134 includes copper (Cu), and the diffusion barriers 132-1 and 132-2 include nickel (Ni).

As shown in FIG. 1D, the adhesion layer 130 is disposed between the diffusion barrier 132-1 and the upper electrode 116 to bond the diffusion barrier 132-1 to the upper electrode 116. The material of the adhesion layer 130 is selected to be compatible with the materials of both the diffusion barrier 132-1 and the upper electrode 116. In one embodiment, the upper electrode 116 includes tin (Sn), the diffusion barrier 132-1 includes nickel (Ni), and the adhesion layer 130 includes gold (Au).

Referring to FIG. 1A, in one embodiment, the light-emitting device 100 further includes an encapsulant 122 disposed over the substrate 102 and covering the substrate 102, the light-emitting element 106, and the conductive connectors CC1 and CC2. In one embodiment, the encapsulant 122 includes an acrylic resin, a silicone, an acrylate-modified polyurethane, an acrylate-modified organosilicon resin, an epoxy resin, an analog thereof, or a combination thereof.

Referring to FIG. 1B, in one embodiment, the light-emitting elements 106-1, 106-2, and 106-3 have rectangular shapes. The light-emitting elements 106-1 and 106-3 have longer sides S1 and S3 extending in a first direction (e.g., the Z direction), and the light-emitting element 106-2 has a longer side S2 extending in a second direction (e.g., the X direction) which is substantially perpendicular to the first direction. As shown in FIG. 1A, the light-emitting elements 106-1 and 106-3 are disposed on the conductive connectors CC1 and CC2, respectively, and do not overlap with the light-emitting element 106-2 when projected along the Y direction. In another embodiment, the light-emitting elements 106-1 and 106-2 partially overlap the light-emitting element 106-3 when projected along the Y direction (not shown).

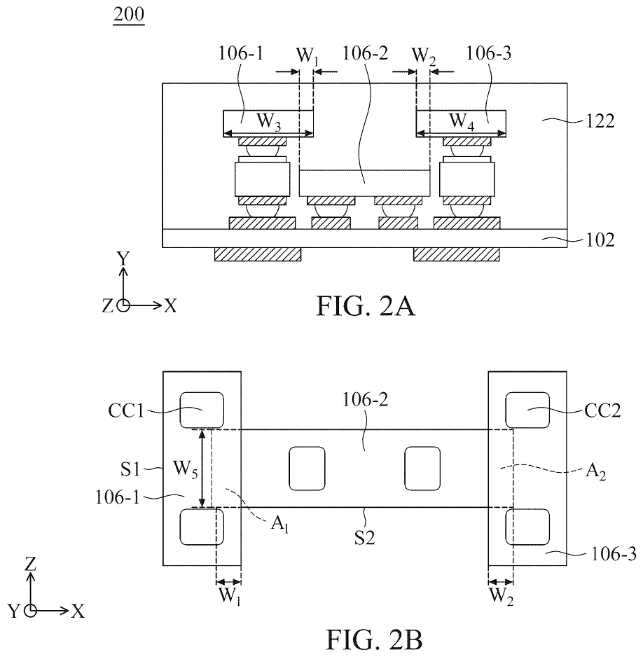

FIG. 2A is a cross-sectional view of a light-emitting device 200 according to another embodiment of the present disclosure. FIG. 2B is a top view of the light-emitting device 200 in FIG. 2A. As shown in FIGS. 2A and 2B, the light-emitting elements 106-1 and 106-3 partially overlap the light-emitting element 106-2.

As shown in FIG. 2B, the light-emitting elements 106-1 and 106-3 partially overlap the light-emitting element 106-2. As shown in FIG. 2A, in the X direction, the portions of light-emitting elements 106-1 and 106-3 that overlap the light-emitting element 106-2 have widths W1 and W2, respectively.

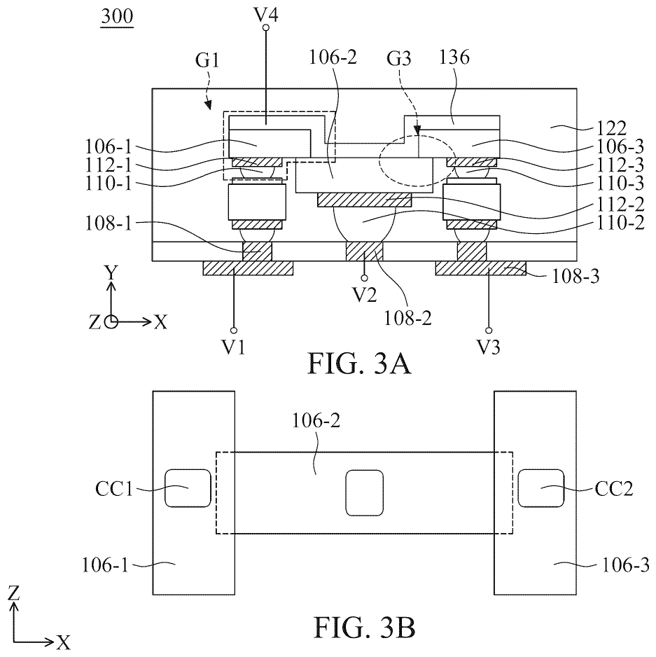

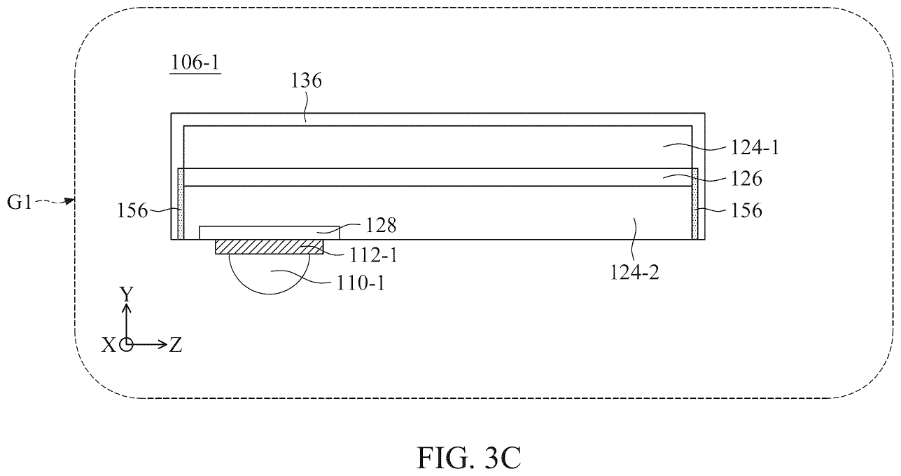

FIG. 3A is a cross-sectional view of a light-emitting device 300 according to embodiment of the present disclosure. FIG. 3B is a top view of the light-emitting device 300 of FIG. 3A. FIG. 3C is a cross-sectional view of region G1 of FIG. 3A in the X direction.

As shown in FIG. 3C, in one embodiment, the light-emitting element 106-1 includes an ohmic contact layer 128, a lower electrode 112-1, and a lower bump 110-1 located below the lower semiconductor layer 124-2, and also includes a common electrode 136 disposed on the upper semiconductor layer 124-1.

As shown in FIG. 3C, the sidewalls of the multi-quantum well structure 126 and the lower semiconductor layer 124-2 are covered by the insulating sidewall 156 to electrically isolate them from the common electrode 136, wherein the common electrode 136 electrically connects to the upper semiconductor layer 124-1. In addition, the contact regions between the light-emitting elements 106-1, 106-3 and the light-emitting element 106-2 do not form an electrical connection (as shown in region G3 of FIG. 3A).

As shown in FIG. 3A, the light-emitting elements 106-1, 106-2, and 106-3 include a lower electrode 112-1, 112-2, 112-3 and a lower bump 110-1, 110-2, 110-3. The lower bumps 110-1, 110-2, and 110-3 are electrically connected to the front electrodes 108-1, 108-2, and 108-3, respectively. The light-emitting elements 106-1, 106-2, and 106-3 are electrically interconnected via the common electrode 136.

As shown in FIG. 3A, in one embodiment, the front electrode 108-1 is at a potential V1, the front electrode 108-2 is at a potential V2, the front electrode 108-3 is at a potential V3, and the common electrode 136 is at a potential V4.

In one embodiment, the material of the common electrode 136 can be referred to the material of the upper electrode 116 as mentioned above. However, because the common electrode 136 covers the light-emitting elements 106-1, 106-2, and 106-3, the common electrode 136 is made of a transparent conductive material.

In one embodiment, the common electrode 136 is selected from metal oxides such as indium tin oxide (ITO), indium oxide (InO), tin oxide (SnO), cadmium tin oxide (CTO), antimony tin oxide (ATO), aluminum-doped zinc oxide (AZO), zinc tin oxide (ZTO), gallium-doped zinc oxide (GZO), indium tungsten oxide (IWO), zinc oxide (ZnO), or indium zinc oxide (IZO).

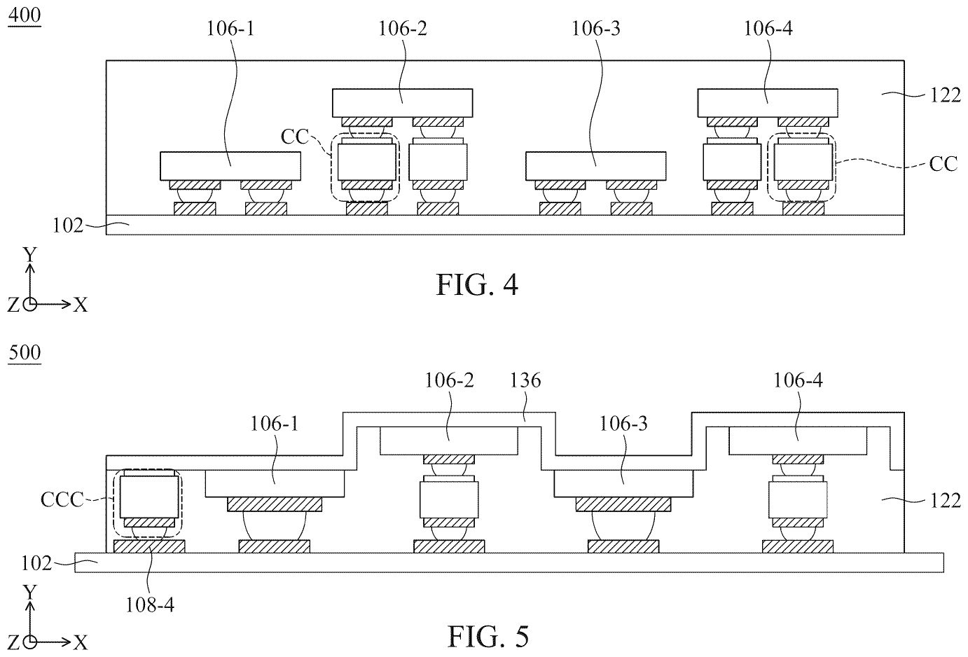

FIG. 4 is a cross-sectional view of a light-emitting device 400 according to a embodiment of the present disclosure. Referring to FIG. 4, in one embodiment, any number of light-emitting elements can be disposed on the substrate 102 of the light-emitting device 400. For example, the light-emitting device 400 includes four light-emitting elements 106-1, 106-2, 106-3, and 106-4. In other embodiments, five or more light-emitting elements, such as five, six, seven, eight, or more (not shown), can be disposed on the substrate 102 of the light-emitting device.

As shown in FIG. 4, in one embodiment, the light-emitting elements 106-2 and 106-4 are not adjacent to each other and are placed on the conductive connectors CC, thereby being raised to a higher elevation in the Y direction than those of the light-emitting elements 106-1 and 106-3. In one embodiment, the light-emitting elements on the substrate 102 are arranged in a matrix along two directions (e.g., the X and Z directions) (not shown). In one embodiment, the conductive connector CC and the conductive connectors CC1 and CC2 have the same or similar structures as mentioned above.

FIG. 5 is a cross-sectional view of a light-emitting device 500 according to a embodiment of the present disclosure. Referring to FIG. 5, in one embodiment, a common electrode 136 is provided on the top surfaces of the light-emitting elements 106-1, 106-2, 106-3, and 106-4 of the light-emitting device 500, and a common conductive connector CCC is provided on the substrate 102.

As shown in FIG. 5, in one embodiment, one end of the common conductive connector CCC is electrically connected to a surface electrode 108-4 of the substrate 102, and the other end is electrically connected to the common electrode 136. The light-emitting elements 106-1, 106-2, 106-3, and 106-4 are electrically interconnected via the common electrode 136, and the common electrode 136 is electrically connected to a surface electrode on the substrate 102 via the common conductive connector CCC. The structure and materials of the common conductive connector CCC can be referred to the conductive connectors CC1 and CC2 mentioned above.

FIG. 6 is a cross-sectional view of a light-emitting device 600 according to a embodiment of the present disclosure. Referring to FIG. 6, in one embodiment, the light-emitting device 600 includes a thin-film transistor (TFT) substrate disposed on the substrate 102.

As shown in FIG. 6, in one embodiment, the TFT substrate includes, from top to bottom, a first insulating layer 148, a second insulating layer 150, a third insulating layer 152, and a fourth insulating layer 154. Interconnections 146-1, 146-2, 146-3, and 158 are disposed within the first insulating layer 148. The interconnections 146-1, 146-2, and 146-3 are respectively electrically connected to the light-emitting elements 106-1, 106-2, and 106-3, and the interconnection 158 is electrically connected to the common conductive connector CCC.

As shown in FIG. 6, transistors TS1, TS2, and TS3, which respectively control the light-emitting elements 106-1, 106-2, and 106-3, are disposed within the second insulating layer 150, the third insulating layer 152, and the fourth insulating layer 154. Each transistor TS1, TS2, and TS3 includes a source electrode (SE-1, SE-2, SE-3), a drain electrode (DE-1, DE-2, DE-3), a gate electrode (GE-1, GE-2, GE-3), and a channel layer (CL-1, CL-2, CL-3).

As shown in FIG. 6, one end of each of the light-emitting elements 106-1, 10 2, and 106-3 is electrically connected to the source electrode SE-1, SE-2, SE-3 of the transistor TS1, TS2, TS3 via the interconnection 146-1, 146-2, 146-3, respectively. The light-emitting elements 106-1, 106-2, and 106-3 are individually controlled by the transistors TS1, TS2, and TS3. As shown in FIG. 6, the other ends of the light-emitting elements 106-1, 106-2, and 106-3 are electrically connected to the common conductive connector CCC via the common electrode 136. In one embodiment, the light-emitting elements 106-1, 106-2, and 106-3 are grounded via the common conductive connector CCC and the interconnection 158.

In one embodiment, the first insulating layer 148, the second insulating layer 150, the third insulating layer 152, and the fourth insulating layer 154 in the TFT substrate include silicon dioxide (SiO₂), silicon nitride (SiNₓ), and aluminum oxide (Al₂O₃).

In one embodiment, the interconnections 146-1, 146-2, 146-3, 158, the source electrodes SE-1, SE-2, SE-3, and the drain electrodes DE-1, DE-2, DE-3 include a metal or a transparent conductive material. The metal includes chromium (Cr), aluminum (Al), nickel (Ni), gold (Au), platinum (Pt), tin (Sn), copper (Cu), or combinations thereof. The transparent conductive material includes indium tin oxide (ITO) or indium zinc oxide (IZO).

In one embodiment, the channel layers CL-1, CL-2, and CL-3 in the TFT substrate include low-temperature polycrystalline silicon (LTPS), indium gallium zinc oxide (IGZO), or amorphous silicon (a-Si).

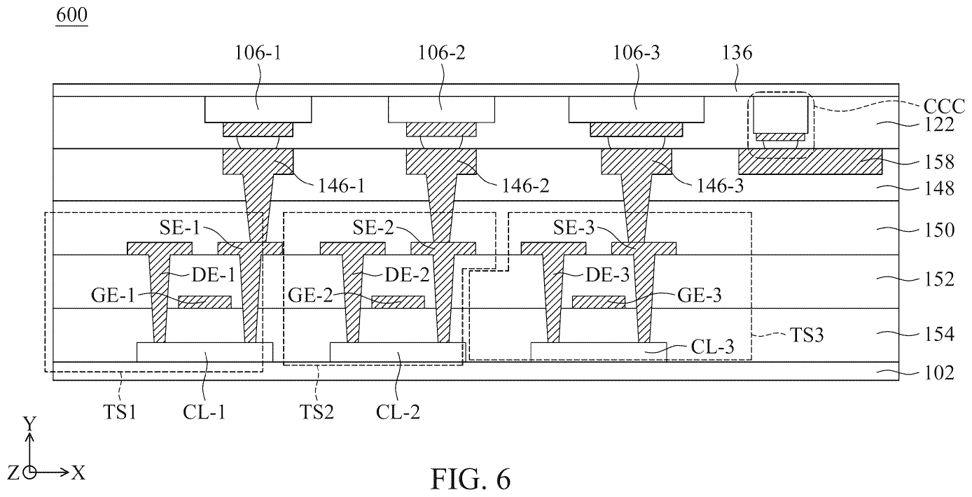

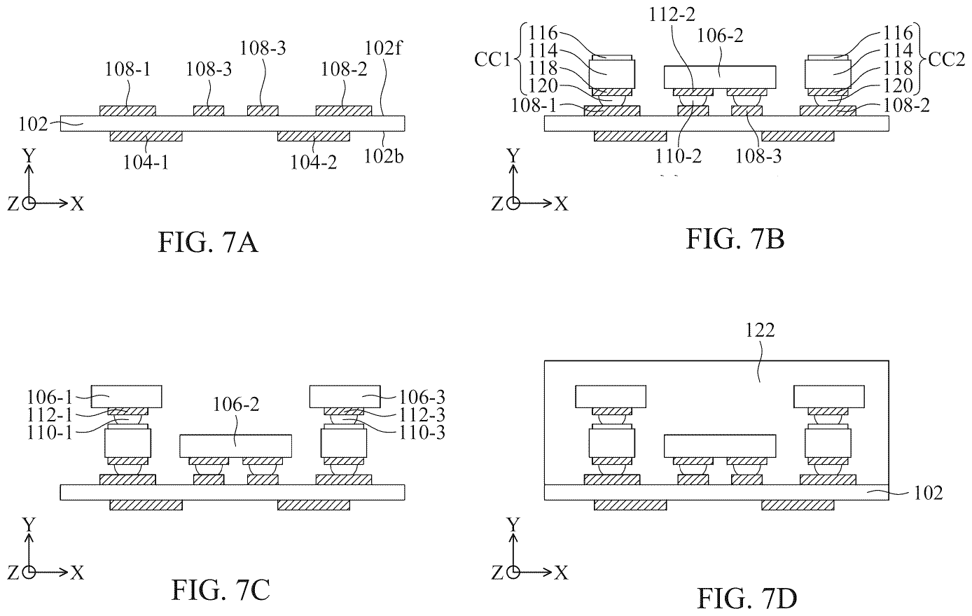

FIGS. 7A to 7D illustrate a manufacturing process of a light-emitting device according to an embodiment of the present disclosure. Referring to FIG. 7A, in one embodiment, the surface electrodes 108-1, 108-2, and 108-3 (hereinafter collectively referred to as the surface electrodes 108) are formed on the front side 102f of the substrate 102, and rear electrodes 104-1 and 104-2 (hereinafter collectively referred to as the rear electrodes 104) are formed on the backside 102b of the substrate 102. In one embodiment, the steps for forming the front electrodes 108 and the rear electrodes 104 include deposition, patterning, and etching processes.

As shown in FIG. 7A, in one embodiment, material layers for the front electrodes 108 and the rear electrodes 104 are first deposited on the front side 102f and the backside 102b of the substrate 102, respectively, by a deposition process. Subsequently, the deposited material layers are patterned to form multiple surface electrodes 108 (e.g., 108-1, 108-2, 108-3) and multiple rear electrodes 104 (e.g., 104-1, 104-2).

In one embodiment, the deposition process includes chemical vapor deposition (CVD), physical vapor deposition (PVD), atomic layer deposition (ALD), high-density plasma chemical vapor deposition (HDPCVD), metal-organic chemical vapor deposition (MOCVD), plasma-enhanced chemical vapor deposition (PECVD), or sputtering.

Referring to FIG. 7B, in one embodiment, after forming the surface electrodes 108 and the rear electrodes 104, the conductive connectors CC1 and CC2 are formed on the front electrodes 108-1 and 108-3 (the steps for forming the conductive connectors are described below), and a lower bump 110-2, a lower electrode 112-2, and a light-emitting element 106-2 are sequentially formed on the front electrode 108-2.

In one embodiment, the lower bump 110-2 and the lower electrode 112-2 are formed by evaporation, sputtering, electroplating, or electroless plating.

In one embodiment, the light-emitting element 106-2 is a light-emitting diode (LED) or a laser diode. In one embodiment, the light-emitting element 106-2 is fixed to the lower electrode 112-2 by eutectic bonding, solder bonding, or adhesive bonding. In one embodiment, the lower bump 110-2 and the lower electrode 112-2 are a part of the electrode of the light-emitting element 106-2.

Referring to FIG. 7C, in one embodiment, after forming the light-emitting element 106-2 and the conductive connectors CC1 and CC2, the light-emitting elements 106-1 and 106-3 are respectively disposed on the conductive connectors CC1 and CC2. The light-emitting elements 106-1 and 106-3 and the light-emitting element 106-2 have the same or similar structures, and the light-emitting elements 106-1 and 106-3 can be fixed onto the conductive connectors CC1 and CC2 by eutectic bonding, solder bonding, or adhesive bonding. In one embodiment, the light-emitting elements 106-1 and 106-3 are fixed to the upper electrodes 116 of the conductive connectors CC1 and CC2 via the lower bumps 110-1 and 110-3.

Referring to FIG. 7D, in one embodiment, after disposing the light-emitting elements 106-1 and 106-3 on the conductive connectors CC1 and CC2, an encapsulant 122 is formed on the substrate 102 to cover the light-emitting elements 106-1, 106-2, and 106-3. The encapsulant 122 includes epoxy resin or silicone.

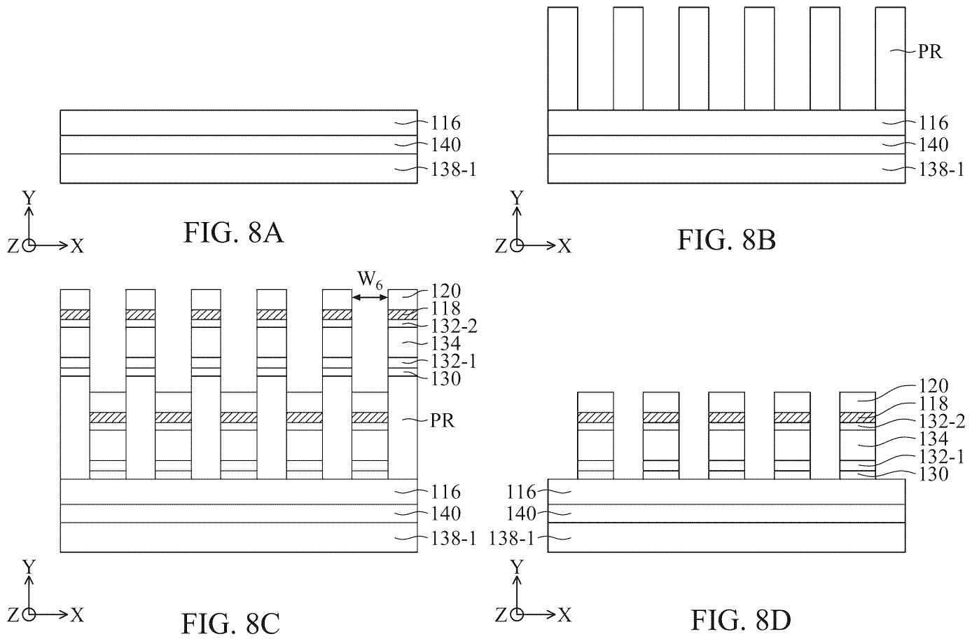

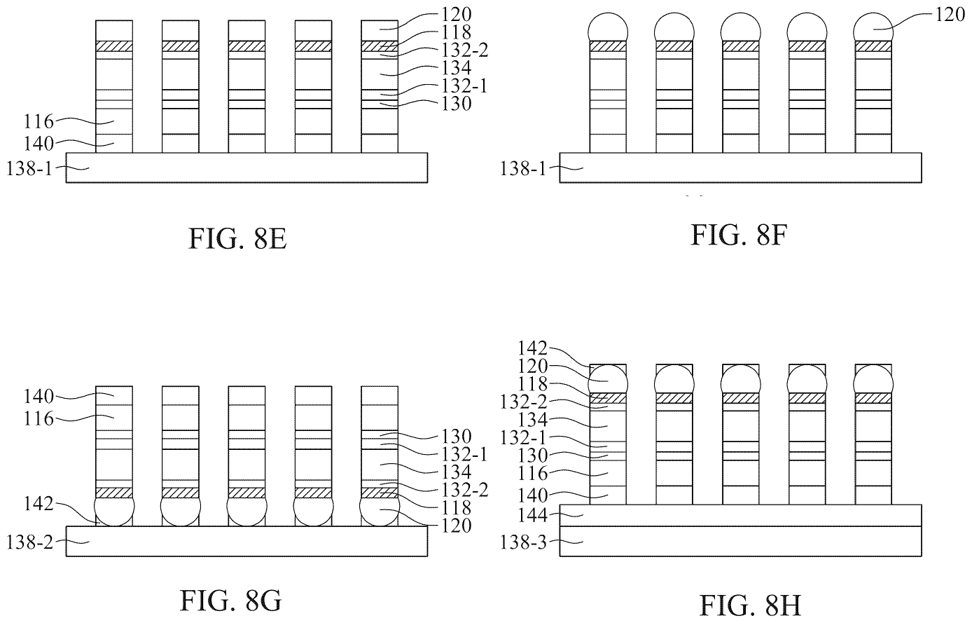

FIGS. 8A to 8H illustrate a manufacturing process of a conductive connector according to an embodiment of the present disclosure. Referring to FIG. 8A, in one embodiment, the manufacturing process of the conductive connector includes forming a silicon oxide layer 140 and a material layer of the upper electrode 116 over a first temporary carrier 138-1. In one embodiment, the first temporary carrier 138-1 includes a plastic substrate, a glass substrate, a sapphire substrate, or other substrate without circuitry (a circuit-less substrate).

In one embodiment, the silicon oxide layer 140 is used to bond the upper electrode 116 to the first temporary carrier 138-1. The silicon oxide layer 140 can be formed by deposition processes such as CVD, PVD, or spin coating. The material layer of the upper electrode 116 can be formed by deposition processes such as PVD, CVD, or ALD.

Referring to FIG. 8B, in one embodiment, after forming the material layer of the upper electrode 116, a photoresist (PR) is formed and patterned on the material layer of the upper electrode 116. The photoresist can be formed by spin coating or another suitable coating process.

Referring to FIG. 8C, in one embodiment, after forming and patterning the PR on the material layer of the upper electrode 116, the material layers of the adhesion layer 130, the first diffusion barrier 132-1, the metal pillar 134, the second diffusion barrier 132-2, the lower electrode 118, and the bump 120 are sequentially formed over the material layer of the upper electrode 116 and the PR.

As shown in FIG. 8C, in one embodiment, the aforementioned film layers or material layers are sequentially deposited over the material layer of the upper electrode 116 and the PR. In this manner, the material layers or the material stack (includes the material layers of the adhesion layer 130, the diffusion barrier 132-1, the metal pillar 134, the diffusion barrier 132-2, the lower electrode 118, and the bump 120) have portions formed in the spaces between the photoresist PR (above the upper electrode 116) and portions formed directly on the photoresist PR. The spacings between the PR define a width W6 of the conductive connector.

In one embodiment, the adhesion layer 130 can be formed by PVD, CVD, ALD, or other suitable processes. PVD includes evaporation or sputter deposition, and CVD includes MOCVD.

In one embodiment, the diffusion barriers 132-1 and 132-2 and the metal pillar 134 can be formed by CVD, PVD, ALD, or other suitable processes. In one embodiment, the step for forming the lower electrode 118 and the bump 120 can be referred to FIG. 7B and the related description.

Referring to FIG. 8D, in one embodiment, after forming the material stack over the material layer of the upper electrode 116 and the photoresist PR, the photoresist PR and a portion of the material layers disposed on the photoresist PR are removed together, while the other portion of the material layers (or material stack) remains on the material layer of the upper electrode 116. In one embodiment, the photoresist PR and the material layers on the photoresist PR are removed by a laser lift-off (LLO) process.

Referring to FIG. 8E, in one embodiment, after removing the photoresist PR and the material layers on it, an etching process is performed. The etching process is used to pattern the material layers of the upper electrode 116 and the silicon oxide layer 140 based on the pattern of the material layers formed on the upper electrode 116.

Referring to FIG. 8F, in one embodiment, after removing portions of the material layers of the upper electrode 116 and the silicon oxide layer 140, a thermal process, such as laser heating, is performed to shape the material layer of the bump 120 to form the bump 120, for example, with a rounded profile.

Referring to FIG. 8G, the material stacks are transferred from the first temporary carrier 138-1 to a second temporary carrier 138-2. In one embodiment, the bump 120 is fixed to the second temporary carrier 138-2 via an adhesive 142, and the first temporary carrier 138-1 is removed. In one embodiment, the adhesive 142 includes an adhesive material which can be softened or decomposed by laser irradiation. The adhesive material includes polyimide (PI) or epoxy.

Referring to FIG. 8H, the material stacks are transferred from the second temporary carrier 138-2 to a third temporary carrier 138-3. In one embodiment, the silicon oxide layer 140 is bonded to the third temporary carrier 138-3 via an adhesive layer 144, and the second temporary carrier 138-2 is removed. In one embodiment, the adhesive layer 144 and the adhesive 142 includes the same or similar materials. After the step shown in FIG. 8H, the adhesive 142 on the bump 120 is removed.

As long as they do not contradict the spirit of the invention or cause conflict, the components of the embodiments of the present disclosure may be freely mixed and matched. Furthermore, the scope of protection of the present disclosure is not limited to the processes, machines, manufacturing methods, compositions of matter, apparatus, methods, and steps described in the specific embodiments disclosed herein. Any processes, machines, manufacturing methods, compositions of matter, apparatus, methods, and steps-whether currently known or developed in the future-that can be understood by those of ordinary skill in the art from the teachings of the present disclosure and that perform substantially the same function or achieve substantially the same result as those described in the embodiments herein, may also be utilized in accordance with the present disclosure. Therefore, the scope of protection of the present disclosure includes the aforementioned processes, machines, manufacturing methods, compositions of matter, apparatus, methods, and steps. Any embodiment or claim of the present disclosure is not required to achieve all of the objectives, advantages, and/or features disclosed herein.

Several embodiments have been outlined above so that those skilled in the art may better understand the concepts of the embodiments of the present disclosure. It should be understood by those skilled in the art that, based on the embodiments of the present disclosure, other processes and structures may be designed or modified to achieve the same purposes and/or advantages as those of the embodiments described herein. It should also be understood by those skilled in the art that such equivalent processes and structures do not depart from the spirit and scope of the present disclosure, and that various changes, substitutions, and modifications can be made without departing from the spirit and scope of the disclosure.

What is claimed is:

1. A light-emitting device, comprising:
a substrate;
a first surface electrode and a second surface electrode, disposed on the substrate;
a first light-emitting element, comprising a first topmost surface, disposed on the substrate and electrically connected to the first surface electrode;
a second light-emitting element, comprising a second topmost surface, disposed on the substrate and electrically connected to the second surface electrode; and
a first conductive connector, comprising a metal stack and a third topmost surface, electrically connecting the first surface electrode and the first light-emitting element;
wherein the third topmost surface is not lower than the second topmost surface.

2. The light-emitting device of claim 1, wherein the first conductive connector directly contacts the first surface electrode, and the first conductive connector further comprises:
a lower electrode, disposed under the metal stack; and
an upper electrode, disposed over the metal stack.

3. The light-emitting device of claim 2, wherein the first light-emitting element further comprises:
an electrode, facing toward the substrate; and
a bump, disposed below the electrode and directly contacting the first conductive connector.

4. The light-emitting device of claim 2, wherein the metal stack comprises a first diffusion barrier, a second diffusion barrier, and a metal pillar disposed between the first diffusion barrier and the second diffusion barrier.

5. The light-emitting device of claim 4, wherein the metal stack further comprises an adhesion layer disposed between the first diffusion barrier and the upper electrode.

6. The light-emitting device of claim 1, wherein the first light-emitting element has first longer side extending in a first direction, the second light-emitting element has a second longer side extending in a second direction which is substantially perpendicular to the first direction,

7. The light-emitting device of claim 1, further comprising:
a third surface electrode, disposed on the substrate; and
a third light-emitting element, electrically connected to the third surface electrode and comprising a fourth topmost surface not lower than the second topmost surface.

8. The light-emitting device of claim 7, wherein the fourth topmost surface and the first topmost surface are substantially located at a same elevation.

9. The light-emitting device of claim 1, further comprising:
a common electrode, electrically connecting the first light-emitting element and the second light-emitting element; and
a common conductive connector, electrically connected to the common electrode.

10. The light-emitting device of claim 9, wherein the common electrode covers the fi light-emitting element, the second light-emitting element, and the common conductive connector.

11. The light-emitting device of claim 9, wherein the common conductive connector and the first conductive connector have a same structure.

12. The light-emitting device of claim 1, wherein, in a cross-sectional view, the first light-emitting element and the second light-emitting element are partially overlapped with each other in a vertical direction.

13. The light-emitting device of claim 1, further comprising an encapsulant covering the substrate, the first light-emitting element, the second light-emitting element, and the first conductive connector.

14. The light-emitting device of claim 1, wherein the first conductive connector has a thickness greater than that of the second light-emitting element.
